(19) United States
(12) Patent Application Publication
(10) Pub. No.: US 2024/0047398 A1
(43) Pub. Date: Feb. 8, 2024

(54) SEMICONDUCTOR DEVICE

(71) Applicant: Murata Manufacturing Co., Ltd., Kyoto-fu (JP)

(72) Inventors: Atsushi KUROKAWA, Nagaokakyo-shi (JP); Mari SAJI, Nagaokakyo-shi (JP)

(73) Assignee: Murata Manufacturing Co., Ltd., Kyoto-fu (JP)

(21) Appl. No.: 18/489,540

(22) Filed: Oct. 18, 2023

Related U.S. Application Data
(63) Continuation of application No. PCT/JP2022/018169, filed on Apr. 19, 2022.

(30) Foreign Application Priority Data
Apr. 23, 2021 (JP) 2021-073300

(51) Int. Cl. H01L 23/00; H01L 29/737; H01L 29/73; H01L 29/732; H01L 25/065

(52) U.S. Cl. CPC H01L 24/13; H01L 24/29; H01L 29/737; H01L 29/7317; H01L 29/7325; H01L 25/0657; H01L 2924/13051; H01L 2225/06517; H01L 2924/014; H01L 2224/1302; H01L 2224/13007; H01L 2224/29022; H01L 2224/29005

(57) ABSTRACT

A semiconductor device includes a semiconductor substrate; at least one first transistor, each first transistor including a mesa structure including one or more semiconductor layers; a first bump overlapping the first transistors and extending in a first direction; and a second bump. The mesa structure includes a first end portion at one end in a second direction and a second end portion at another end in the second direction. In plan view, an outer periphery of the first bump includes a first side and a second side extending in the first direction and arranged next to each other in the second direction. The first side is closer to the second bump than the second side in the second direction. The first end portion and the second end portion of the mesa structure are between the first side and the second side.

### CROSS-REFERENCE TO RELATED APPLICATIONS

This application claims benefit of priority to International Patent Application No. PCT/JP2022/018169, filed Apr. 19, 2022, and to Japanese Patent Application No. 2021-073300, filed Apr. 23, 2021, the entire contents of each are incorporated herein by reference.

### BACKGROUND

### Technical Field

The present disclosure relates to a semiconductor device.

### Background Art

International Publication No. 2015/104967 describes a semiconductor device including a heterojunction bipolar transistor. The semiconductor device described in International Publication No. 2015/104967 includes a bump on a mesa structure (for example, a multilayer structure including a collector layer, a base layer, and an emitter layer) of the transistor.

### SUMMARY

When the bump overlaps the entire region of the mesa structure of the transistor, heat dissipation performance can be improved (that is, thermal resistance can be reduced). However, the characteristics of the transistor may be degraded due to stress applied by the bump. Thus, there is a possibility that the reliability of the semiconductor device will be reduced.

Accordingly, the present disclosure provides a semiconductor device in which stress generated in a mesa structure of a transistor can be reduced.

A semiconductor device according to an aspect of the present disclosure includes a semiconductor substrate; at least one or more first transistors provided on the semiconductor substrate, each first transistor including a mesa structure including one or more semiconductor layers; a wiring layer overlapping the mesa structure; a first bump overlapping the at least one or more first transistors and electrically connected to the wiring layer, the first bump extending in a first direction parallel to the semiconductor substrate; and a second bump facing with the first bump in a second direction orthogonal to the first direction and extending in the first direction. The mesa structure includes a first end portion at one end in the second direction and a second end portion at another end in the second direction, the first end portion being closer to the second bump than the second end portion in the second direction. In plan view in a direction perpendicular to the semiconductor substrate, an outer periphery of the first bump includes a first side and a second side extending in the first direction and arranged next to each other in the second direction, the first side being closer to the second bump than the second side in the second direction, the first end portion and the second end portion of the mesa structure being disposed between the first side and the second side. In plan view in the direction perpendicular to the semiconductor substrate, a first distance between the first side and the first end portion of the mesa structure in the second direction is greater than a second distance between the second side and the second end portion of the mesa structure in the second direction.

A semiconductor device according to another aspect of the present disclosure includes a semiconductor substrate; at least one or more first transistors provided on the semiconductor substrate, each first transistor including a mesa structure including one or more semiconductor layers; a wiring layer overlapping the mesa structure; a first bump overlapping the at least one or more first transistors and electrically connected to the wiring layer, the first bump extending in a first direction parallel to the semiconductor substrate; and a second bump on a side of a geometric center of the semiconductor substrate opposite to a side on which the first bump is disposed. The mesa structure includes a first end portion at one end in a second direction orthogonal to the first direction and a second end portion at another end in the second direction, the first end portion being closer to the geometric center of the semiconductor substrate than the second end portion in the second direction. In plan view in a direction perpendicular to the semiconductor substrate, an outer periphery of the first bump includes a first side and a second side extending in the first direction and arranged next to each other in the second direction, the first side being closer to the geometric center of the semiconductor substrate than the second side in the second direction, the first end portion and the second end portion of the mesa structure being between the first side and the second side. In plan view in the direction perpendicular to the semiconductor substrate, a first distance between the first side and the first end portion of the mesa structure in the second direction is greater than a second distance between the second side and the second end portion of the mesa structure in the second direction.

The present disclosure provides a semiconductor device in which stress generated in a mesa structure of a transistor can be reduced.

### BRIEF DESCRIPTION OF THE DRAWINGS

FIG. 1 is a plan view of a semiconductor device according to a first embodiment;

FIG. 2 is a sectional view of FIG. 1 taken along line II-II′;

FIG. 3 is a plan view of a semiconductor device according to a second embodiment;

FIG. 4 is a sectional view of a semiconductor device according to a third embodiment;

FIG. 5 is a sectional view illustrating a cross-sectional shape of a mesa structure of a transistor according to a first modification;

FIG. 6 is a sectional view illustrating a cross-sectional shape of a mesa structure of a transistor according to a second modification;

FIG. 7 is a plan view illustrating a plurality of transistors and a bump overlapping the transistors according to a third modification;

FIG. 8 is a plan view illustrating a plurality of transistors and a bump overlapping the transistors according to a fourth modification.

### DETAILED DESCRIPTION

Semiconductor devices according to embodiments of the present disclosure will now be described in detail with reference to the drawings. The embodiments do not limit the present disclosure. It is needless to say that each embodiment is an exemplification and that configurations in different embodiments may be partly replaced or combined with each other. In the second and following embodiments, description of features in common with the first embodiment will be omitted, and only differences will be described. In particular, the same or similar effects obtained by the same or similar configurations will not be described in each embodiment.

### First Embodiment

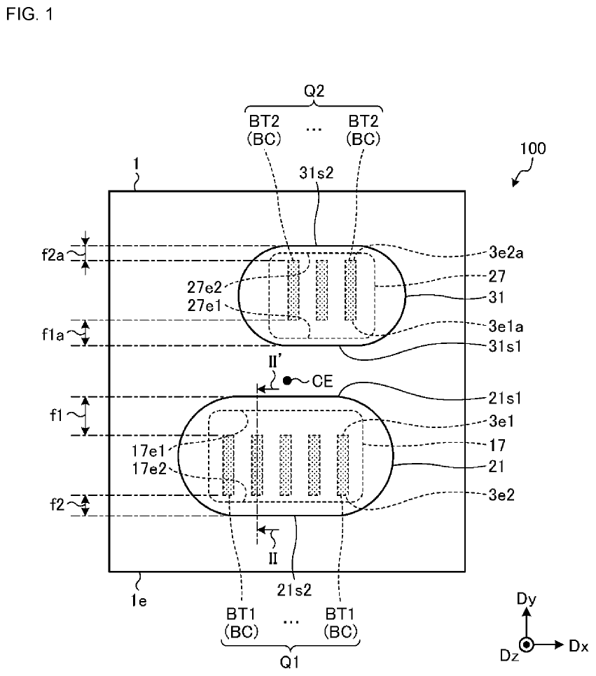

FIG. 1 is a plan view of a semiconductor device according to a first embodiment. FIG. 1 does not illustrate the structures of transistors (first transistors BT1 and second transistors BT2) in detail, and schematically shows the arrangement of mesa structures BC, each of which includes a collector layer 3 and a base layer 4 of each transistor.

As illustrated in FIG. 1, a semiconductor device 100 includes a semiconductor substrate 1, a first transistor group Q1, a second transistor group Q2, a first bump 21, and a second bump 31.

In the following description, one direction along a plane parallel to a surface of the semiconductor substrate 1 will be referred to as a first direction Dx. A direction orthogonal to the first direction Dx on the plane parallel to the surface of the semiconductor substrate 1 will be referred to as a second direction Dy. A direction orthogonal to the first direction Dx and the second direction Dy will be referred to as a third direction Dz. The third direction Dz is a direction perpendicular to the surface of the semiconductor substrate 1. In this specification, plan views show positional relationships as viewed in the third direction Dz.

The first transistor group Q1 and the second transistor group Q2 are provided on the surface of the semiconductor substrate 1. The first transistor group Q1 and the second transistor group Q2 are arranged next to each other with an interval therebetween in the second direction Dy. The first transistor group Q1 includes a plurality of first transistors BT1. The second transistor group Q2 includes a plurality of second transistors BT2. The first transistors BT1 and the second transistors BT2 are heterojunction bipolar transistors (HBTs).

The first transistors BT1 and the second transistors BT2 are also referred to as unit transistors. The unit transistors are defined as the smallest transistors that constitute the first transistor group Q1 or the second transistor group Q2. The first transistors BT1 are electrically connected in parallel and constitute the first transistor group Q1. The second transistors BT2 are electrically connected in parallel and constitute the second transistor group Q2.

The first transistors BT1 of the first transistor group Q1 are arranged in the first direction Dx. Each of the first transistors BT1 extends in the second direction Dy. Similarly, the second transistors BT2 of the second transistor group Q2 are arranged in the first direction Dx. Each of the second transistors BT2 extends in the second direction Dy.

In the example illustrated in FIG. 1, the first transistor group Q1 includes five first transistors BT1, and the second transistor group Q2 includes three second transistors BT2. However, the numbers and arrangements of the first transistors BT1 and the second transistors BT2 are examples, and may be changed as appropriate.

The semiconductor substrate 1 has a geometric center CE positioned between the first transistor group Q1 and the second transistor group Q2 arranged next each other in the second direction Dy. The semiconductor substrate 1 has a quadrangular (rectangular) shape in plan view, and the geometric center CE coincides with the intersection of two diagonals of the semiconductor substrate 1.

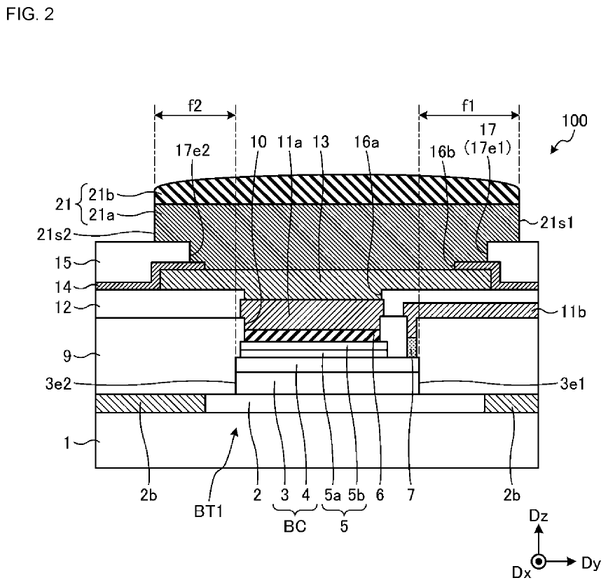

The first bump 21 overlaps the first transistors BT1 of the first transistor group Q1. The first bump 21 is electrically connected to the first transistors BT1 through an opening 17 provided in an organic insulating film 15 (see FIG. 2). The first bump 21 has an oval shape in plan view, and extends in the first direction Dx along the direction in which the first transistors BT1 are arranged.

In plan view, the outer periphery of the first bump 21 includes a first side 21s1 and a second side 21s2 extending in the first direction Dx and arranged next to each other in the second direction Dy. The first side 21s1 of the first bump 21 is closer to the geometric center CE of the semiconductor substrate 1 than the second side 21s2 in the second direction Dy.

The first bump 21 overlaps the entire regions of the first transistors BT1. More specifically, the mesa structures BC of the first transistors BT1 each have a first end portion 3e1 at one end in the second direction Dy and a second end portion 3e2 at the other end in the second direction Dy. The first end portion 3e1 is closer to the second bump 31 than the second end portion 3e2 in the second direction Dy. In other words, the first end portion 3e1 of the mesa structure BC of each first transistor BT1 is closer to the geometric center CE of the semiconductor substrate 1 than the second end portion 3e2. The first end portion 3e1 and the second end portion 3e2 of the mesa structure BC of each first transistor BT1 are between the first side 21s1 and the second side 21s2 of the first bump 21.

The opening 17 has a first opening end portion 17e1 and a second opening end portion 17e2 that are next to each other in the second direction Dy. In plan view, the first opening end portion 17e1 is closer to the second bump 31 than the second opening end portion 17e2. In addition, in plan view, the first opening end portion 17e1 is between the first end portion 3e1 of each mesa structure BC and the second bump 31. In addition, the first end portion 3e1 and the second end portion 3e2 of each mesa structure BC are between the first opening end portion 17e1 and the second opening end portion 17e2.

Similarly, the second bump 31 overlaps the second transistors BT2 of the second transistor group Q2. The second bump 31 is electrically connected to the second transistors BT2 through an opening 27 provided in an insulating film (not illustrated). The second bump 31 has an oval shape in plan view, and extends in the first direction Dx along the direction in which the second transistors BT2 are arranged.

In plan view, the outer periphery of the second bump 31 includes a first side 31s1 and a second side 31s2 extending in the first direction Dx and arranged next to each other in the second direction Dy. The first side 31s1 of the second bump 31 is closer to the geometric center CE of the semiconductor substrate 1 than the second side 31s2 in the second direction Dy. In other words, the second bump 31 and the first bump 21 extend parallel to each other, and are arranged next to each other in the second direction Dy. The first side 21s1 of the first bump 21 faces the first side 31s1 of the second bump 31 in the second direction Dy.

The second bump 31 overlaps the entire regions of the second transistors BT2. More specifically, the mesa structures BC of the second transistors BT2 each have a first end portion 3e1a at one end in the second direction Dy and a second end portion 3e2a at the other end in the second direction Dy. The first end portion 3e1a is closer to the first bump 21 than the second end portion 3e2a in the second direction Dy. In other words, the first end portion 3e1a of the mesa structure BC of each second transistor BT2 is closer to the geometric center CE of the semiconductor substrate 1 than the second end portion 3e2a. The first end portion 3e1a and the second end portion 3e2a of the mesa structure BC of each second transistor BT2 are between the first side 31s1 and the second side 31s2 of the second bump 31.

The opening 27 has a first opening end portion 27e1 and a second opening end portion 27e2 that are next to each other in the second direction Dy. In plan view, the first opening end portion 27e1 is closer to the first bump 21 than the second opening end portion 27e2. In addition, in plan view, the first opening end portion 27e1 is between the first end portion 3e1a of each mesa structure BC and the first bump 21. In addition, the first end portion 3e1a and the second end portion 3e2a of each mesa structure BC are between the first opening end portion 27e1 and the second opening end portion 27e2.

Thus, the first bump 21 that overlaps at least one first transistor BT1 extends in the first direction Dx, and a long side (first side 21s1) of the outer periphery of the first bump 21 is next to a long side (first side 31s1) of the outer periphery of the other second bump 31. In this configuration, stress generated due to the first bump 21 and the second bump 31 is increased at the sides of the first bump 21 and the second bump 31 that face each other (that is, at the sides facing the geometric center CE of the semiconductor substrate 1).

In the present embodiment, the first bump 21 overlaps the first transistors BT1 of the first transistor group Q1, and the first transistors BT1 are positioned unevenly relative to the first side 21s1 and the second side 21s2 of the first bump 21. More specifically, in plan view in a direction perpendicular to the semiconductor substrate 1, a first distance f1 between the first side 21s1 of the first bump 21 and the first end portion 3e1 of each mesa structure BC in the second direction Dy is greater than a second distance f2 between the second side 21s2 of the first bump 21 and the second end portion 3e2 of each mesa structure BC in the second direction Dy.

Assume that an end portion 1e is one of end portions of the semiconductor substrate 1 in the second direction Dy that is closer to the first bump 21 than to the second bump 31. The distance between the end portion 1e of the semiconductor substrate 1 and the first side 21s1 of the first bump 21 is greater than the distance between the end portion 1e of the semiconductor substrate 1 and the second side 21s2 of the first bump 21. In other words, the first distance f1 at a location adjacent to the geometric center CE of the semiconductor substrate 1 is greater than the second distance f2 at a location adjacent to the end portion 1e of the semiconductor substrate 1. When one first bump 21 overlaps the plurality of first transistors BT1, the first distance f1 and the second distance f2 are the averages for the first transistors BT1.

Thus, the first end portion 3e1 of the mesa structure BC of each first transistor BT1 is separated from the first side 21s1 of the first bump 21 at which a relatively large stress is generated (that is, from the first side 21s1 of the first bump 21 that is adjacent to the second bump 31). Therefore, stress generated in the mesa structure BC of each first transistor BT1 due to the first bump 21 can be reduced.

Similarly, the second bump 31 overlaps the second transistors BT2 of the second transistor group Q2, and the second transistors BT2 are positioned unevenly relative to the first side 31s1 and the second side 31s2 of the second bump 31. More specifically, in plan view in the direction perpendicular to the semiconductor substrate 1, a first distance f1a between the first side 31s1 of the second bump 31 and the first end portion 3e1a of the mesa structure BC of each second transistor BT2 in the second direction Dy is greater than a second distance f2a between the second side 31s2 of the second bump 31 and the second end portion 3e2a of the mesa structure BC of each second transistor BT2 in the second direction Dy.

The cross-sectional structure of the semiconductor device 100 will now be described in detail. FIG. 2 is a sectional view of FIG. 1 taken along line Although FIG. 2 illustrates one of the first transistors BT1 of the first transistor group Q1 and the first bump 21, description of the multilayer structure including the first transistor BT1 of the first transistor group Q1 and the first bump 21 can also be applied to the multilayer structure including each second transistor BT2 of the second transistor group Q2 and the second bump 31.

As illustrated in FIG. 2, the first transistor BT1 of the semiconductor device 100 includes a subcollector layer 2, the collector layer 3, the base layer 4, an emitter layer 5, an emitter electrode 6, a base electrode 7, and a collector electrode (not illustrated). The subcollector layer 2, the collector layer 3, the base layer 4, and the emitter layer 5 of the first transistor BT1 are laminated in that order on the semiconductor substrate 1.

The mesa structure BC according to present embodiment is composed of the collector layer 3 and the base layer 4. The first end portion 3e1 and the second end portion 3e2 of the mesa structure BC are defined as end portions of the collector layer 3 in the second direction Dy, more specifically, by positions of bottom end portions of the collector layer 3 that are in contact with the subcollector layer 2. The emitter layer 5 includes an intrinsic emitter layer 5a and an emitter mesa layer 5b that are laminated together. In other words, the emitter layer 5 has an emitter mesa structure.

The emitter electrode 6, a first wiring line 11a, and a second wiring line 13 (emitter wiring line) are laminated in that order on the emitter layer 5. An inorganic insulating film 14 (insulating film) and the organic insulating film 15 cover the second wiring line 13 and have openings 16b and 17, respectively, in a region that at least overlaps the collector layer 3. The first bump 21 is provided on the organic insulating film 15 and is electrically connected to the second wiring line 13 through the openings 16b and 17.

More specifically, the semiconductor substrate 1 is, for example, a semi-insulating gallium arsenide (GaAs) substrate. The subcollector layer 2 is provided on the semiconductor substrate 1. The subcollector layer 2 is a heavily doped n-type GaAs layer, and has a thickness of, for example, about 0.5 The collector layer 3 is provided on the subcollector layer 2. The collector layer 3 is an n-type GaAs layer, and has a thickness of, for example, about 1 The base layer 4 is provided on the collector layer 3. The base layer 4 is a p-type GaAs layer, and has a thickness of, for example, about 100 nm.

The emitter layer 5 is provided on the base layer 4. The emitter layer 5 includes the intrinsic emitter layer 5a and the emitter mesa layer 5b provided on the intrinsic emitter layer 5a. The intrinsic emitter layer 5a and the emitter mesa layer 5b are arranged in that order from the base layer 4. The intrinsic emitter layer 5a is an n-type indium gallium phosphide (InGaP) layer, and has a thickness of, for example, 30 nm or more and 40 nm or less (i.e., from 30 nm to 40 nm). The emitter mesa layer 5b is composed of a heavily doped n-type GaAs layer and a heavily doped n-type InGaAs layer. The heavily doped n-type GaAs layer and the heavily doped n-type InGaAs layer each have a thickness of, for example, about 100 nm. The heavily doped n-type InGaAs layer is provided in the emitter mesa layer 5b to provide an ohmic contact between the emitter mesa layer 5b and the emitter electrode 6.

The base layer 4 and the collector layer 3 are formed by forming layers on the semiconductor substrate 1 by epitaxial growth and then performing an etching process, and constitute the mesa structure BC. The collector layer 3 may include a lower portion that is not removed, and the mesa structure BC may be formed of the base layer 4 and an upper portion of the collector layer 3.

The collector electrode (not illustrated) is provided on the subcollector layer 2 and is in contact with the subcollector layer 2. The collector electrode is, for example, next to the mesa structure BC (the base layer 4 and the collector layer 3) in the first direction Dx. The collector electrode includes a multilayer film including, for example, a gold-germanium (AuGe) film, a nickel (Ni) film, and a gold (Au) film laminated in that order. The AuGe film has a film thickness of, for example, 60 nm. The Ni film has a film thickness of, for example, 10 nm. The Au film has a film thickness of, for example, 200 nm.

The base electrode 7 is provided on the base layer 4 and is in contact with the base layer 4. The base electrode 7 is a multilayer film including a Ti film, a Pt film, and an Au film laminated in that order. The Ti film has a film thickness of, for example, 50 nm. The Pt film has a film thickness of, for example, 50 nm. The Au film has a film thickness of, for example, 200 nm.

The emitter electrode 6 is provided on the emitter mesa layer 5b of the emitter layer 5 and is in contact with the emitter mesa layer 5b. The emitter electrode 6 is a titanium (Ti) film. The Ti film has a film thickness of, for example, 50 nm.

Isolation regions 2b are provided next to the subcollector layer 2 on the semiconductor substrate 1. The isolation regions 2b are insulating regions formed by ion implantation. The isolation regions 2b provide insulation between elements (between the first transistors BT1).

The first insulating film 9 is provided on the subcollector layer 2 and the isolation regions 2b, and covers the emitter electrode 6, the base electrode 7, and the collector electrode (not illustrated). The first insulating film 9 is, for example, a silicon nitride (SiN) layer. The first insulating film 9 may be composed of a single layer or include a plurality of nitride layers or oxide layers laminated together. The first insulating film 9 may have a multilayer structure including an SiN layer and a resin layer.

First wiring lines 11a and 11b are provided on the first insulating film 9. The first insulating film 9 has a first insulating-film opening 10, and the first wiring line 11a is connected to the emitter electrode 6 through the first insulating-film opening 10. Similarly, the first wiring line 11b is connected to the base electrode 7 through an opening provided in the first insulating film 9. Although not illustrated in FIG. 2, a first wiring line 11c connected to the collector electrode is also provided on the first insulating film 9.

The first wiring lines 11a and 11b are, for example, an Au film. The Au film has a film thickness of, for example, about 1 μm. A second insulating film 12 is provided on the first insulating film 9 to cover the first wiring lines 11a and 11b. The second insulating film 12 is made of a material similar to that of the first insulating film 9. The second insulating film 12 may be a single-layer film composed of an SiN layer, for example, or have a multilayer structure including an SiN layer and a resin layer. The second insulating film 12 has a second insulating-film opening 16a in a region overlapping the first wiring line 11a.

The second wiring line 13 is provided on the second insulating film 12, and is connected to the first wiring line 11a through the second insulating-film opening 16a. The second wiring line 13 is electrically connected to the emitter layer 5 by the first wiring line 11a. The material of the second wiring line 13 is mainly a metal material, such as Au or Cu. The second wiring line 13 is formed to overlap the entirety of the first transistor BT1 including the collector layer 3, the base layer 4, and the emitter layer 5.

The inorganic insulating film 14 covers the second wiring line 13, and the organic insulating film 15 is provided on the inorganic insulating film 14. The inorganic insulating film 14 is, for example, an inorganic protective film made of an inorganic material containing at least one or more of SiN and silicon oxynitride (SiON). The inorganic insulating film 14 may be omitted as necessary.

The organic insulating film 15 is, for example, an organic protective film made of an organic material, such as polyimide or BCB. The inorganic insulating film 14 (insulating film) and the organic insulating film 15 respectively have the openings 16b and 17 in a region overlapping the second wiring line 13.

The first bump 21 is formed to overlap the openings 16b and 17 and be in contact with the organic insulating film 15 along an opening edge of the opening 17. As illustrated in FIG. 2, the first bump 21 is a pillar bump, and has a multilayer structure including a metal post 21a and solder 21b. The metal post 21a is made of, for example, Cu, and has a film thickness of about 10 μm or more and about 50 μm or less (i.e., from about 10 μm to about 50 μm). The solder 21b is made of, for example, Sn or an alloy of Sn and Ag, and has a film thickness of about 10 μm or more and about 30 μm or less (i.e., from about 10 μm or more and about 30 μm). A metal layer (under bump metal (UBM)) may be provided below the first bump 21.

The positions of the first side 21s1 and the second side 21s2 of the first bump 21 in the second direction Dy are positions of the lower end portions of the side surfaces of the first bump 21, that is, positions at which the side surfaces of the first bump 21 are in contact with the organic insulating film 15. The first distance f1 between the first side 21s1 of the first bump 21 and the first end portion 3e1 of the mesa structure BC of the first transistor BT1 in the second direction Dy and the second distance f2 between the second side 21s2 of the first bump 21 and the second end portion 3e2 of the mesa structure BC of the first transistor BT1 in the second direction Dy can be regarded as the distances from the lower end portions of the side surfaces of the first bump 21 in the second direction Dy to the respective end portions of the collector layer 3 of the mesa structure BC in the second direction Dy.

The first opening end portion 17e1 and the second opening end portion 17e2 of the opening 17 are defined by inner walls of the organic insulating film 15 facing each other in the second direction Dy.

Stress concentrates in regions close to the first side 21s1 and the second side 21s2 of the first bump 21, more specifically, at the first opening end portion 17e1 and the second opening end portion 17e2 of the opening 17. The stress is lower in regions that are outside the first side 21s1 and the second side 21s2 of the first bump 21 and in which the organic insulating film 15 is provided than in a region overlapping the first bump 21.

The Young's modulus of the organic insulating film 15 is less than those of the metal materials forming the second wiring line 13 and the first bump 21 and the semiconductor materials forming the first transistor BT1. Therefore, thermal stress is reduced in the regions overlapping the organic insulating film 15. Although the opening 17 is formed in the organic insulating film 15, the opening 17 may be formed in the inorganic insulating film 14. Alternatively, an inorganic insulating film may be laminated instead of the organic insulating film 15. Also in this case, the thermal stress of the first bump 21 can be reduced.

As a comparative example, a simulation was performed to calculate the distribution of thermal stress obtained when a semiconductor device in which the first distance f1 and the second distance f2 are equal is mounted with solder at 260° C. and then returned to room temperature. For example, when the first distance f1 and the second distance f2 satisfy f1=f2=37.5 μm, stress generated at the first end portion 3e1 of the mesa structure BC of the first transistor BT1 (that is, the first end portion 3e1 close to the second bump 31) is as high as 121% of the stress generated at the second end portion 3e2 of the mesa structure BC (that is, the second end portion 3e2 away from the second bump 31).

As an example of the present embodiment, a simulation was performed to calculate the distribution of thermal stress obtained when the semiconductor device 100 in which the first distance f1 is greater than the second distance f2 is mounted with solder at 260° C. and then returned to room temperature. For example, when the first distance f1 is 41 μm and the second distance f2 is 34 μm, stress generated at the first end portion 3e1 of the mesa structure BC of the first transistor BT1 (that is, the first end portion 3e1 close to the second bump 31) is 10% lower than that in the above-described comparative example. The stress generated at the second end portion 3e2 of the mesa structure BC (that is, the second end portion 3e2 away from the second bump 31) is similar to that in the above-described comparative example.

As described above, the semiconductor device 100 according to the present embodiment includes the semiconductor substrate 1; at least one or more first transistors BT1 provided on the semiconductor substrate 1, each first transistor BT1 including a mesa structure BC including a plurality of semiconductor layers (for example, the collector layer 3 and the base layer 4); the wiring layer (second wiring line 13) overlapping the mesa structure BC; the first bump 21 overlapping the at least one or more first transistors BT1 and electrically connected to the wiring layer, the first bump 21 extending in the first direction Dx parallel to the semiconductor substrate 1; and the second bump 31 next to the first bump 21 in the second direction Dy orthogonal to the first direction Dx and extending in the first direction Dx. The mesa structure BC includes the first end portion 3e1 at one end in the second direction Dy and the second end portion 3e2 at the other end in the second direction Dy, and the first end portion 3e1 is closer to the second bump 31 than the second end portion 3e2 in the second direction Dy. In plan view in the direction perpendicular to the semiconductor substrate 1, the outer periphery of the first bump 21 includes the first side 21s1 and the second side 21s2 extending in the first direction Dx and arranged next to each other in the second direction Dy. The first side 21s1 is closer to the second bump 31 than the second side 21s2 in the second direction Dy, and the first end portion 3e1 and the second end portion 3e2 of the mesa structure BC are between the first side 21s1 and the second side 21s2. In plan view in the direction perpendicular to the semiconductor substrate 1, the first distance f1 between the first side 21s1 and the first end portion 3e1 of the mesa structure BC in the second direction Dy is greater than the second distance f2 between the second side 21s2 and the second end portion 3e2 of the mesa structure BC in the second direction Dy.

Thus, the semiconductor device 100 is structured such that the first bump 21 overlaps the entire regions of the mesa structures BC of the first transistors BT1, so that heat dissipation performance can be improved. In addition, the semiconductor device 100 is structured such that the first bump 21 and the second bump 31 are arranged next to each other, and that the first distance f1 is greater than the second distance f2. Therefore, the first end portion 3e1 of each mesa structure BC is separated from the first side 21s1 of the first bump 21 at which stress concentrates, so that stress generated in the mesa structure BC of each first transistor BT1 can be reduced.

Although FIG. 2 illustrates the first bump 21 and the mesa structure BC of the first transistor BT1, the second bump 31 and the mesa structure BC of each second transistor BT2 (see FIG. 1) have a similar structure as described above. That is, the first distance f1a between the first side 31s1 of the second bump 31 and the first end portion 3e1a of the mesa structure BC of each second transistor BT2 in the second direction Dy is greater than the second distance f2a between the second side 31s2 of the second bump 31 and the second end portion 3e2a of the mesa structure BC of each second transistor BT2 in the second direction Dy. Therefore, stress generated at the first end portion 3e1a of the mesa structure BC of each second transistor BT2 can also be reduced.

The first distance f1 and the second distance f2 are defined as distances from the mesa structure BC composed of the collector layer 3 and the base layer 4, but may be defined as distances from the mesa structure of the emitter layer 5 to the first side 21s1 and the second side 21s2 of the first bump 21. However, stress can be more effectively reduced when the mesa structure BC, which has a greater step height, is used. Although the mesa structure BC includes the entirety of the collector layer 3 in this example, the mesa structure BC may be composed of the base layer 4 and a portion of the collector layer 3. In this example, only the first bump 21 and the second bump 31 are provided on the semiconductor substrate 1. As a modification, a third bump may be provided in a region between the first bump 21 and the second bump 31. An effect similar to the above-described effect can be provided for reducing stress applied to a mesa due to the first bump 21 or the second bump 31.

### Second Embodiment

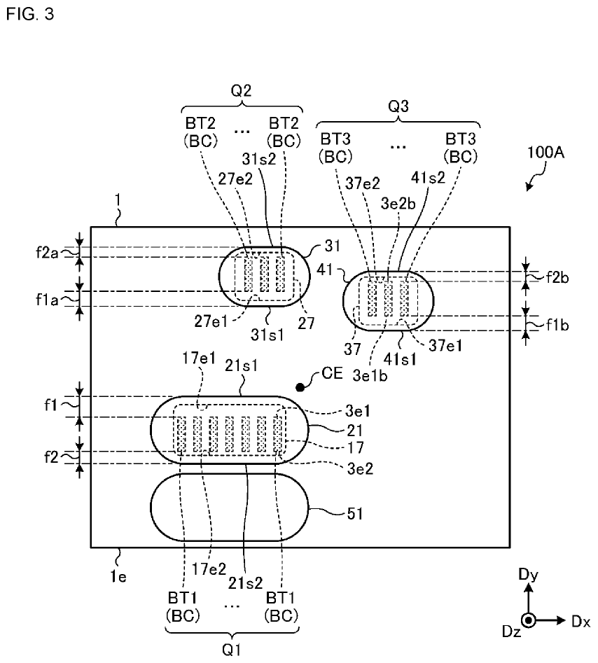

FIG. 3 is a plan view of a semiconductor device according to a second embodiment. The second embodiment described below differs from the first embodiment in that a third bump 41 and a fourth bump 51 are provided. The relative arrangement between the first transistor group Q1 (first transistors BT1) and the first bump 21 and the relative arrangement between the second transistor group Q2 (second transistors BT2) and the second bump 31 are same as those in the first embodiment, and description thereof will not be repeated.

As illustrated in FIG. 3, in a semiconductor device 100A according to the second embodiment, the third bump 41 overlaps a third transistor group Q3 (third transistors BT3). The multilayer structure of the third bump 41 and the third transistors BT3 is similar to that in the first embodiment (see FIG. 2). More specifically, the third bump 41 is electrically connected to the third transistors BT3 through an opening 37 provided in an organic insulating film 15. A first end portion 3e1b and a second end portion 3e2b of each mesa structure BC are between a first opening end portion 37e1 and a second opening end portion 37e2 of the opening 37 and between a first side 41s1 and a second side 41s2 of the third bump 41.

The third bump 41 and the third transistor group Q3 are positioned in an oblique direction crossing the first direction Dx and the second direction Dy from the first bump 21 and the first transistor group Q1. The third bump 41 and the third transistor group Q3 are on a side of the geometric center CE of the semiconductor substrate 1 opposite to the side on which the first bump 21 and the first transistor group Q1 are.

The third bump 41 and the third transistor group Q3 are next to the second bump 31 and the second transistor group Q2 in the first direction Dx. The distance (minimum distance) between the first bump 21 and the third bump 41 is greater than the distance (minimum distance) between the second bump 31 and the third bump 41.

The fourth bump 51 is next to the first bump 21 and the first transistor group Q1 in the second direction Dy. More specifically, the fourth bump 51 is closer to the end portion 1e of the semiconductor substrate 1 (further away from the geometric center CE) than the first bump 21 and the first transistor group Q1. The fourth bump 51 is, for example, a terminal electrically connected to the collector electrodes of the first transistors BT1 of the first transistor group Q1, and does not overlap transistors, such as the first transistors BT1. The distance (minimum distance) between the first bump 21 and the second bump 31 is greater than the distance (minimum distance) between the first bump 21 and the fourth bump 51. The distance (minimum distance) between the first bump 21 and the third bump 41 is greater than the distance (minimum distance) between the first bump 21 and the fourth bump 51.

In a structure including a plurality of bumps (first to fourth bumps 21 to 51) as described above, stress generated in the mesa structures BC is greater when the distances between the bumps are large than when the distances between the bumps is small.

When focusing on the first bump 21 and the first transistor group Q1 (first transistors BT1), stress generated in each mesa structure BC is relatively low at the second end portion 3e2 that is adjacent to the fourth bump 51 close thereto, and is relatively high at the first end portion 3e1 that is adjacent to the second bump 31 away therefrom. Similarly to the above-described first embodiment, the first distance f1 at a side adjacent to the second bump 31 is greater than the second distance f2 at a side adjacent to the fourth bump 51. In other words, the first distance f1 at a side adjacent to the geometric center CE of the semiconductor substrate 1 is greater than the second distance f2 at a side adjacent to the end portion 1e of the semiconductor substrate 1. Thus, stress generated in the mesa structure BC of each first transistor BT1 can be reduced.

When focusing on the second bump 31 and the second transistor group Q2 (second transistors BT2), stress generated in each mesa structure BC is relatively low at a side adjacent to the third bump 41 close thereto, and is relatively high at a side adjacent to the first bump 21 away therefrom. Therefore, similarly to the above-described first embodiment, the first distance f1a at the side adjacent to the first bump 21 (adjacent to the geometric center CE of the semiconductor substrate 1) is greater than the second distance f2a. Thus, stress generated in the mesa structure BC of each second transistor BT2 can be reduced.

When focusing on the third bump 41 and the third transistor group Q3 (third transistors BT3), the third bump 41 is in an oblique direction from the first bump 21 and the first transistor group Q1 (first transistors BT1) and is not next to the first bump 21 and the first transistor group Q1 in the second direction Dy. Also in this case, the third bump 41 is away from the first bump 21 with the geometric center CE of the semiconductor substrate 1 therebetween, and stress is greater at the first side 41s1 of the third bump 41 close to the geometric center CE of the semiconductor substrate 1 than at the second side 41s2 of the third bump 41 away from the geometric center CE of the semiconductor substrate 1.

In the mesa structure BC of each third transistor BT3, the first end portion 3e1b is closer to the geometric center CE of the semiconductor substrate 1 than the second end portion 3e2b in the second direction Dy. A first distance f1b at a side close to the geometric center CE of the semiconductor substrate 1 is greater than a second distance f2b at a side away from the geometric center CE of the semiconductor substrate 1. More specifically, the third bump 41 and the third transistor group Q3 (third transistors BT3) are structured such that the first distance f1b between the first side 41s1, which is close to the geometric center CE of the semiconductor substrate 1, and the first end portion 3e1b of each mesa structure BC in the second direction Dy is greater than the second distance f2b between the second side 41s2, which is away from the geometric center CE of the semiconductor substrate 1, and the second end portion 3e2b of each mesa structure BC in the second direction Dy. Thus, stress generated in the mesa structure BC of each third transistor BT3 can be reduced.

In FIG. 3, the bumps have an oval shape extending in the first direction Dx. However, the bumps are not limited to this. For example, a plurality of circular bumps may be arranged next to other.

### Third Embodiment

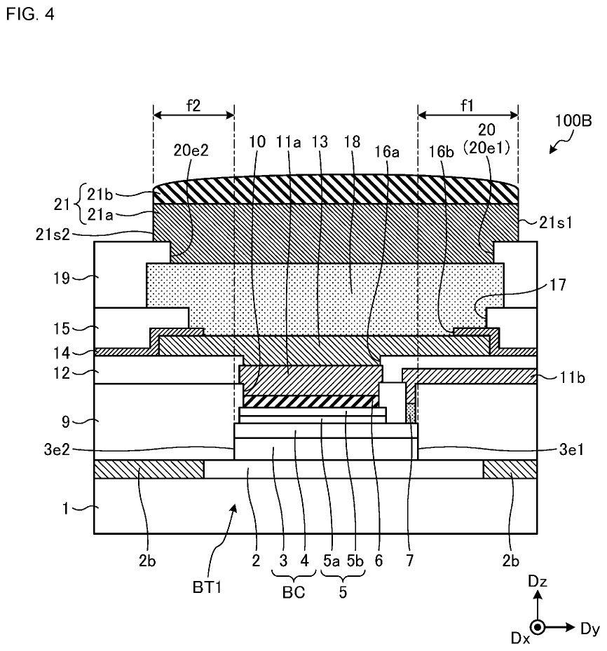

FIG. 4 is a sectional view of a semiconductor device according to a third embodiment. The third embodiment described below differs from the first and second embodiments in that a third wiring line 18 is provided between the second wiring line 13 and the first bump 21. The third wiring line 18 is also referred to as a rewiring layer. The multilayer structure from the semiconductor substrate 1 to the second wiring line 13 is similar to that in the above-described first embodiment (FIG. 2), and description thereof will not be repeated.

As illustrated in FIG. 4, in a semiconductor device 100B according to the third embodiment, the third wiring line 18 is provided on the organic insulating film 15 and the inorganic insulating film 14, and is connected to the second wiring line 13 through the openings 16b and 17. The third wiring line 18 is electrically connected to the emitter layer 5 by the second wiring line 13 and the first wiring line 11a. The material of the third wiring line 18 is, for example, the same metal material as that of the second wiring line 13.

An organic insulating film 19 covers the third wiring line 18. The organic insulating film 19 (insulating film) has an opening 20 in a region overlapping the third wiring line 18.

The first bump 21 is formed to overlap the opening 20 and be in contact the organic insulating film 19 along an opening edge (a first opening end portion 20e1 and a second opening end portion 20e2) of the opening 20. In the present embodiment, the first distance f1 is defined as the distance between the first side 21s1 of the first bump 21 and the first end portion 3e1 of the mesa structure BC of the first transistor BT1 in the second direction Dy. The second distance f2 is defined as the distance between the second side 21s2 of the first bump 21 and the second end portion 3e2 of the mesa structure BC of the first transistor BT1 in the second direction Dy.

Also in the present embodiment, the first distance f1 is greater than the second distance f2. Thus, stress generated in the mesa structure BC of the first transistor BT1 due to the first bump 21 can be reduced.

The structure of the third embodiment may also be applied to the above-described semiconductor devices 100 and 100A according to the first and second embodiments.

Although the semiconductor devices 100, 100A, and 100B described as examples in the above embodiments are structured such that one bump (for example, the first bump 21) overlaps a plurality of transistors (for example, the first transistors BT1), the semiconductor device is not limited to this. The semiconductor device may be structured such that one bump overlaps one transistor. Although a pillar bump is described as an example of a bump, the bump may be, for example, a solder bump or a stud bump instead of a pillar bump.

The materials, thicknesses, dimensions, etc., of elements in the above-described embodiments are merely examples, and may be changed as appropriate. The materials and thicknesses of the subcollector layer 2, the collector layer 3, the base layer 4, the emitter layer 5, and various wiring lines may also be changed as appropriate.

### Modifications

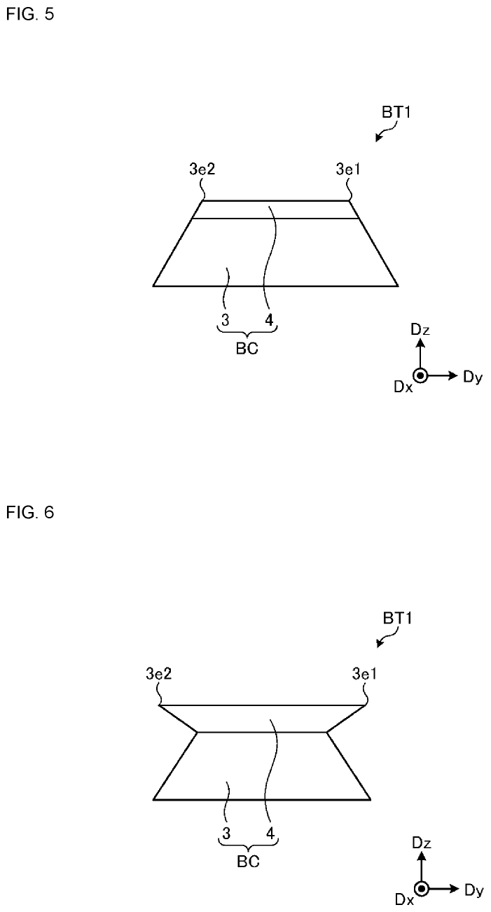

When each mesa structure BC does not have a rectangular shape in cross section as in the first to third embodiments, the first end portion (for example, the first end portion 3e1) and the second end portion (second end portion 3e2) of the mesa structure BC of each transistor (for example, each first transistor BT1) are defined as end portions of the mesa structure BC in a region closest to the bump. This will be described in detail with respect to FIGS. 5 and 6.

FIG. 5 is a sectional view illustrating a cross-sectional shape of a mesa structure of a transistor according to a first modification. FIG. 6 is a sectional view illustrating a cross-sectional shape of a mesa structure of a transistor according to a second modification. In the first modification illustrated in FIG. 5, the cross-sectional shape of the mesa structure BC is a trapezoid. One of the sides of the trapezoid facing each other in the third direction Dz (side of the base layer 4 facing the first bump 21) is shorter than the other one of the sides of the trapezoid facing each other in the third direction Dz (side of the collector layer 3 facing the semiconductor substrate 1). In the second modification illustrated in FIG. 6, the cross-sectional shape of the mesa structure BC is obtained by connecting a trapezoid in which one of the sides facing each other in the third direction Dz is longer than the other, and a trapezoid in which one of the sides facing each other in the third direction Dz is shorter than the other. The trapezoids are connected such that the shorter sides thereof are in contact with each other. When the mesa structure BC does not have a rectangular shape in cross section as in FIGS. 2 and 4, the first end portion 3e1 of the mesa structure BC at one end in the second direction Dy and the second end portion 3e2 at the other end are end portions of the base layer 4 of the mesa structure BC on a surface facing the first bump 21. In FIG. 6, the long side of the base layer 4 (side facing the first bump 21) and the long side of the collector layer 3 (side facing the semiconductor substrate 1) have similar lengths. However, the structure is not limited to this. The long side of the base layer 4 may be longer than the long side of the collector layer 3. Alternatively, the long side of the collector layer 3 may be longer than the long side of the base layer 4.

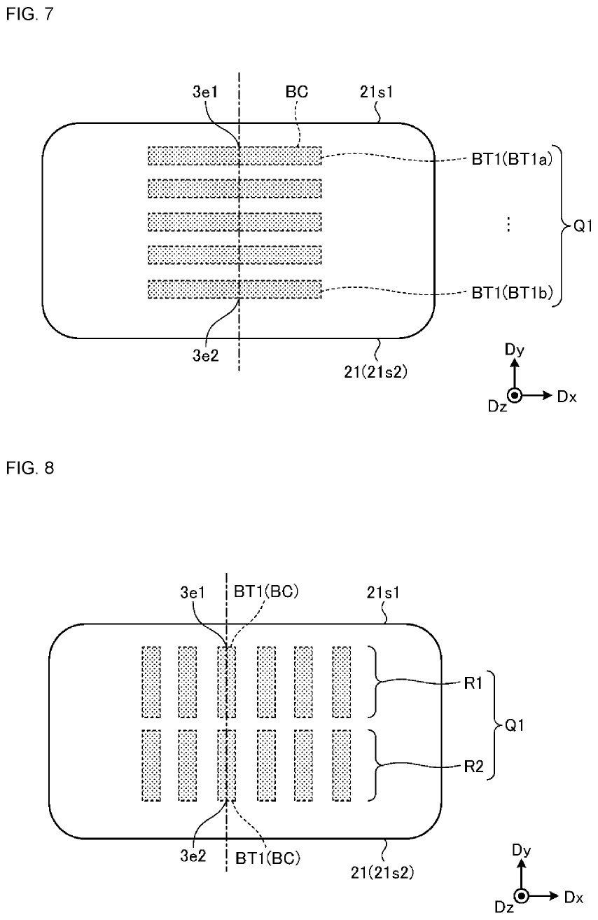

The semiconductor devices described as examples in the first to third embodiments are structured such that one bump (for example, the first bump 21) overlaps a plurality of transistors (for example, the first transistors BT1). The transistors have long sides extending in the second direction Dy, and are arranged in the first direction Dx. However, the structure is not limited to this. This will be described with reference to FIGS. 7 and 8.

FIG. 7 is a plan view illustrating a plurality of transistors and a bump overlapping the transistors according to a third modification. In the third modification illustrated in FIG. 7, the transistors (first transistors BT1) have long sides extending in the first direction Dx, and are arranged in the second direction Dy. In this case, as illustrated in FIG. 7, the first end portion 3e1 of the mesa structures BC is an end portion of a first sub transistor BT1a, which is one of the transistors (first transistors BT1) that is closest to the first side 21s1 on the outer periphery of the first bump 21 in plan view. The second end portion 3e2 of the mesa structures BC is an end portion of a second sub transistor BT1b, which is one of the transistors (first transistors BT1) that is closest to the second side 21s2 on the outer periphery of the first bump 21 in plan view. More specifically, the first end portion 3e1 of the mesa structures BC is an end portion of the mesa structure BC of the first sub transistor BT1a, the end portion being closest to the first side 21s1 in the second direction Dy. The second end portion 3e2 of the mesa structures BC is an end portion of the mesa structure BC of the second sub transistor BT1b, the end portion being closest to the second side 21s2 in the second direction Dy.

FIG. 8 is a plan view illustrating a plurality of transistors and a bump overlapping the transistors according to a fourth modification. In the fourth modification illustrated in FIG. 8, a plurality of rows R1 and R2 of transistors (first transistors BT1) arranged in the first direction Dx are provided, and a bump (first bump 21) overlaps the rows of transistors (first transistor BT1). In this case, as illustrated in FIG. 8, the first end portion 3e1 of the mesa structures BC is an end portion of the transistors (first transistors BT1) belonging to the row R1 that is closest to the first side 21s1 on the outer periphery of the first bump 21 in plan view. The second end portion 3e2 of the mesa structures BC is an end portion of the transistors (first transistors BT1) belonging to the row R2 that is closest to the second side 21s2 on the outer periphery of the bump 21 in plan view. More specifically, the first end portion 3e1 of the mesa structures BC is an end portion of the first transistors BT1 belonging to the row R1 closest to the first side 21s1 in the second direction Dy, the end portion being adjacent to the first side 21s1. The second end portion 3e2 of the mesa structures BC is an end portion of the first transistors BT1 belonging to the row R2 closest to the second side 21s2 in the second direction Dy, the end portion being adjacent to the second side 21s2.

The above-described embodiments are intended to facilitate understanding of the present disclosure, and not to limit interpretation of the present disclosure. The present disclosure can be modified or improved without departing from the spirit thereof, and includes equivalents thereto.

What is claimed is:

1. A semiconductor device comprising:
a semiconductor substrate;
at least one first transistor on the semiconductor substrate, each first transistor including a mesa structure including one or more semiconductor layers;
a wiring layer covering the mesa structure;
a first bump overlapping the at least one first transistor and electrically connected to the wiring layer, the first bump extending in a first direction parallel to the semiconductor substrate; and
a second bump extending in the first direction and facing the first bump in a second direction orthogonal to the first direction,
wherein
the mesa structure includes a first end portion at one end in the second direction and a second end portion at another end in the second direction, the first end portion being closer to the second bump than the second end portion in the second direction,
in plan view in a direction perpendicular to the semiconductor substrate, an outer periphery of the first bump includes a first side and a second side extending in the first direction and next to each other in the second direction, the first side being closer to the second bump than the second side in the second direction, the first end portion and the second end portion of the mesa structure being between the first side and the second side, and
in plan view in the direction perpendicular to the semiconductor substrate, a first distance between the first side and the first end portion of the mesa structure in the second direction is greater than a second distance between the second side and the second end portion of the mesa structure in the second direction.

2. The semiconductor device according to claim 1, wherein
one of end portions of the semiconductor substrate in the second direction is closer to the first bump than to the second bump, and a distance between the one of the end portions and the first side is greater than a distance between the one of the end portions and the second side.

3. A semiconductor device comprising:
a semiconductor substrate;
at least one first transistor on the semiconductor substrate, each first transistor including a mesa structure including one or more semiconductor layers;
a wiring layer covering the mesa structure;
a first bump overlapping the at least one or more first transistors and electrically connected to the wiring layer, the first bump extending in a first direction parallel to the semiconductor substrate; and
a second bump on a side of a geometric center of the semiconductor substrate opposite to a side on which the first bump is,
wherein
the mesa structure includes a first end portion at one end in a second direction orthogonal to the first direction and a second end portion at another end in the second direction, the first end portion being closer to the geometric center of the semiconductor substrate than the second end portion in the second direction,
in plan view in a direction perpendicular to the semiconductor substrate, an outer periphery of the first bump includes a first side and a second side extending in the first direction and arranged next to each other in the second direction, the first side being closer to the geometric center of the semiconductor substrate than the second side in the second direction, the first end portion and the second end portion of the mesa structure being between the first side and the second side, and
in plan view in the direction perpendicular to the semiconductor substrate, a first distance between the first side and the first end portion of the mesa structure in the second direction is greater than a second distance between the second side and the second end portion of the mesa structure in the second direction.

4. The semiconductor device according to claim 1, comprising:
a collector layer on the semiconductor substrate;
a base layer on the collector layer; and
an emitter layer on the base layer,
wherein the mesa structure includes at least a portion of the collector layer and the base layer.

5. The semiconductor device according to claim 1, further comprising:
an insulating film covering the wiring layer and having an opening in a region overlapping at least the mesa structure,
wherein
the first bump is electrically connected to the wiring layer through the opening, and
the insulating film is an inorganic protective film including an inorganic material.

6. The semiconductor device according to claim 1, further comprising:
at least one second transistor on the semiconductor substrate, each second transistor including a mesa structure including one or more semiconductor layers,
wherein the second bump overlaps the at least one second transistor.

7. The semiconductor device according to claim 2, comprising:
a collector layer on the semiconductor substrate;
a base layer on the collector layer; and
an emitter layer on the base layer,
wherein the mesa structure includes at least a portion of the collector layer and the base layer.

8. The semiconductor device according to claim 3, comprising:
a collector layer on the semiconductor substrate;
a base layer on the collector layer; and
an emitter layer on the base layer,
wherein the mesa structure includes at least a portion of the collector layer and the base layer.

9. The semiconductor device according to claim 2, further comprising:
an insulating film covering the wiring layer and having an opening in a region overlapping at least the mesa structure,
wherein
the first bump is electrically connected to the wiring layer through the opening, and
the insulating film is an inorganic protective film including an inorganic material.

10. The semiconductor device according to claim 3, further comprising:
an insulating film covering the wiring layer and having an opening in a region overlapping at least the mesa structure,
wherein
the first bump is electrically connected to the wiring layer through the opening, and
the insulating film is an inorganic protective film including an inorganic material.

11. The semiconductor device according to claim 4, further comprising:
an insulating film covering the wiring layer and having an opening in a region overlapping at least the mesa structure,
wherein
the first bump is electrically connected to the wiring layer through the opening, and
the insulating film is an inorganic protective film including an inorganic material.

12. The semiconductor device according to claim 7, further comprising:
an insulating film covering the wiring layer and having an opening in a region overlapping at least the mesa structure,
wherein
the first bump is electrically connected to the wiring layer through the opening, and
the insulating film is an inorganic protective film including an inorganic material.

13. The semiconductor device according to claim 8, further comprising:
an insulating film covering the wiring layer and having an opening in a region overlapping at least the mesa structure,
wherein
the first bump is electrically connected to the wiring layer through the opening, and
the insulating film is an inorganic protective film including an inorganic material.

14. The semiconductor device according to claim 2, further comprising:
at least one second transistor on the semiconductor substrate, each second transistor including a mesa structure including one or more semiconductor layers,
wherein the second bump overlaps the at least one second transistor.

15. The semiconductor device according to claim 3, further comprising:
at least one second transistor on the semiconductor substrate, each second transistor including a mesa structure including one or more semiconductor layers,
wherein the second bump overlaps the at least one second transistor.

16. The semiconductor device according to claim 4, further comprising:
at least one second transistor on the semiconductor substrate, each second transistor including a mesa structure including one or more semiconductor layers,
wherein the second bump overlaps the at least one second transistor.

17. The semiconductor device according to claim 7, further comprising:
at least one second transistor on the semiconductor substrate, each second transistor including a mesa structure including one or more semiconductor layers,
wherein the second bump overlaps the at least one second transistor.

18. The semiconductor device according to claim 8, further comprising:
at least one second transistor on the semiconductor substrate, each second transistor including a mesa structure including one or more semiconductor layers,
wherein the second bump overlaps the at least one second transistor.

19. The semiconductor device according to claim 9, further comprising:
at least one second transistor on the semiconductor substrate, each second transistor including a mesa structure including one or more semiconductor layers,
wherein the second bump overlaps the at least one second transistor.

20. The semiconductor device according to claim 10, further comprising:
at least one second transistor on the semiconductor substrate, each second transistor including a mesa structure including one or more semiconductor layers,
wherein the second bump overlaps the at least one second transistor.
